(19) United States
(12) Patent Application Publication
(10) Pub. No.: US 2016/0372697 A1
(43) Pub. Date: Dec. 22, 2016

(54) ORGANIC ELECTROLUMINESCENT ELEMENT AND METHOD FOR MANUFACTURING SAME

(71) Applicant: Kabushiki Kaisha Toshiba, Minato-ku (JP)

(72) Inventors: Hayato KAKIZOE, Yokohama (JP); Tomoko SUGIZAKI, Kawasaki (JP); Tomoaki SAWABE, Taito (JP); Keiji SUGI, Fujisawa (JP); Tomio ONO, Yokohama (JP)

(73) Assignee: Kabushiki Kaisha Toshiba, Minato-ku (JP)

(21) Appl. No.: 15/251,488

(22) Filed: Aug. 30, 2016

Related U.S. Application Data
(63) Continuation of application No. PCT/JP2014/080502, filed on Nov. 18, 2014.

(30) Foreign Application Priority Data
Mar. 20, 2014 (JP) 2014-058135

(51) Int. Cl. H01L 51/52; H01L 51/56

(52) U.S. Cl. CPC H01L 51/5215; H01L 51/56; H01L 51/5234; H01L 51/5253; H01L 2251/308; H01L 2251/301

(57) ABSTRACT

According to one embodiment, a method for manufacturing an organic electroluminescent element includes forming a first electrode including a first portion, a second portion, a third portion, a fourth portion, and a fifth portion. The method further includes forming an insulating layer on the first portion, the second portion, and the third portion. The method further includes forming an organic layer on the fifth portion. The method further includes forming a conductive layer having a light transmittance lower than a light transmittance of the first electrode so that the conductive layer is formed on the fourth portion, the insulating layer, and the organic layer, and causing a light transmittance of a portion of the conductive layer positioned on the fourth portion to be higher than a light transmittance of a portion of the conductive layer positioned on the organic layer.

### CROSS-REFERENCE TO RELATED APPLICATIONS

This is a continuation application of International Application PCT/JP2014/080502, filed on Nov. 18, 2014; the entire contents of which are incorporated herein by reference.

### FIELD

Embodiments described herein relate generally to an organic electroluminescent element and a method for manufacturing the same.

### BACKGROUND

Organic electroluminescent elements are being utilized in planar light sources and the like. Because organic electroluminescent elements have planar light emission and are thin and lightweight, there are expectations for applications of organic electroluminescent elements in lighting appliances and light sources that could not be realized conventionally.

Such an organic electroluminescent element includes a positive electrode, a negative electrode, and an organic light-emitting layer that is provided between the positive electrode and the negative electrode. There is a transmission-type organic electroluminescent element that is made to be light-transmissive by making the negative electrode thin, providing the negative electrode in a fine wire configuration, and providing openings in the negative electrode. It is desirable to increase the reliability of such a transmission-type organic electroluminescent element.

### BRIEF DESCRIPTION OF THE DRAWINGS

FIG. 1 is a schematic cross-sectional view showing an organic electroluminescent element according to a first embodiment;

FIG. 2A and FIG. 2B are schematic cross-sectional views showing the organic electroluminescent element according to the first embodiment;

FIG. 3A to FIG. 3C are schematic views showing organic electroluminescent elements of a reference example;

FIG. 4 is a microscope photograph showing a portion of the organic electroluminescent element of the reference example;

FIG. 5A to FIG. 5E show manufacturing processes of the organic electroluminescent element according to the first embodiment;

FIG. 6 is a schematic cross-sectional view showing an organic electroluminescent element according to a second embodiment;

FIG. 7A and FIG. 7B are schematic cross-sectional views showing the organic electroluminescent element according to the second embodiment; and

FIG. 8A to FIG. 8E show manufacturing processes of the organic electroluminescent element according to the second embodiment.

### DETAILED DESCRIPTION

According to one embodiment, a method for manufacturing an organic electroluminescent element includes forming a first electrode on a first surface of a substrate. The first electrode is light-transmissive. The first electrode includes a first portion, a second portion, a third portion, a fourth portion, and a fifth portion. The second portion is separated from the first portion in a plane parallel to the first surface. The third portion is provided between the first portion and the second portion. The fourth portion is provided between the first portion and the third portion. The fifth portion is provided between the third portion and the second portion. The method further includes forming an insulating layer on the first portion, the second portion, and the third portion. The method further includes forming an organic layer on the fifth portion. The method further includes forming a conductive layer having a light transmittance lower than a light transmittance of the first electrode so that the conductive layer is formed on the fourth portion, the insulating layer, and the organic layer, and causing a light transmittance of a portion of the conductive layer positioned on the fourth portion to be higher than a light transmittance of a portion of the conductive layer positioned on the organic layer.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### First Embodiment

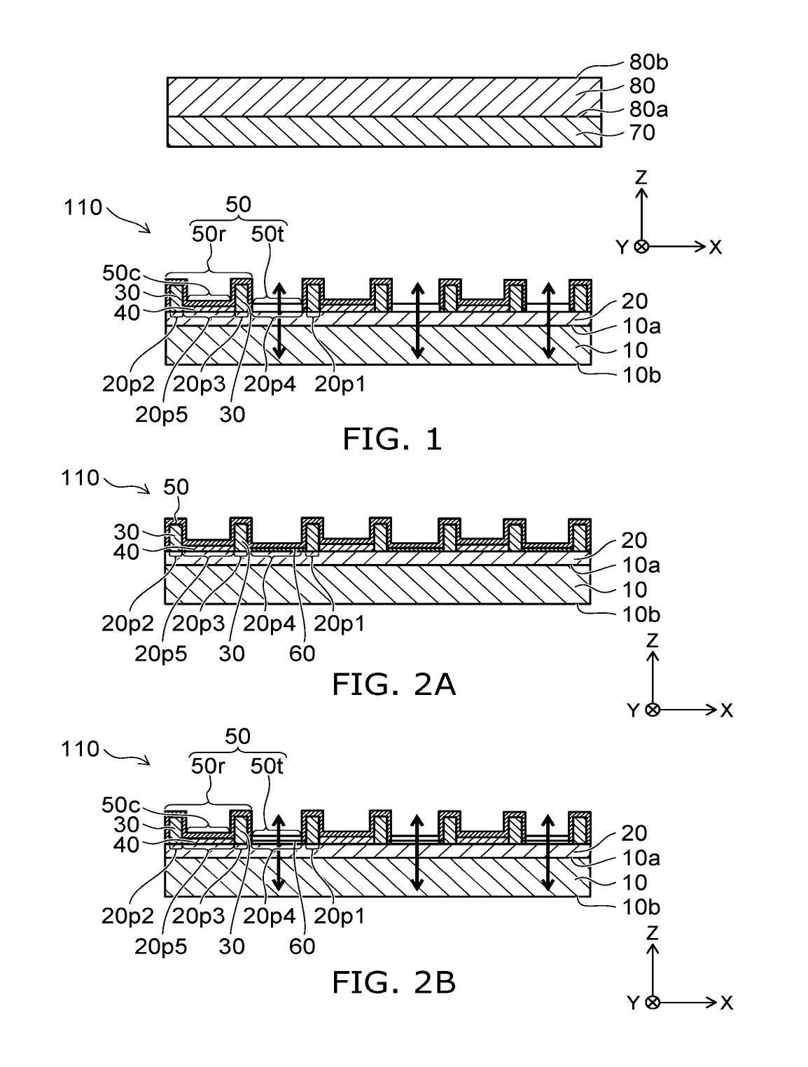

FIG. 1 is a schematic cross-sectional view showing an organic electroluminescent element according to a first embodiment.

FIG. 2A and FIG. 2B are schematic cross-sectional views showing the organic electroluminescent element according to the first embodiment.

FIG. 1 shows the organic electroluminescent element 110. FIG. 2A shows the organic electroluminescent element 110 when a second electrode layer 50 is formed on the entire substrate surface. FIG. 2B shows the organic electroluminescent element 110 after forming the second electrode layer 50 when a chemical reaction of making a portion of the second electrode layer 50 transparent has progressed.

As shown in FIG. 1, a substrate 10, a first electrode 20, an insulating layer 30, an organic layer 40, and the second electrode layer 50 are provided in the organic electroluminescent element 110. The organic electroluminescent element 110 is sealed with a sealing substrate 80 with a hygroscopic material 70 interposed. The second electrode layer 50 includes a light reflecting portion 50r that is light-reflective, and a light-transmitting portion 50t.

The substrate 10 has a first surface 10a and a second surface 10b. The second surface 10b is the surface on the side opposite to the first surface 10a. The sealing substrate 80 has a third surface 80a and a fourth surface 80b. The fourth surface 80b is the surface on the side opposite to the third surface 80a. The first surface 10a of the substrate 10 opposes the third surface 80a of the sealing substrate 80.

A direction from the substrate 10 toward the sealing substrate 80 is taken as a Z-axis direction. One direction perpendicular to the Z-axis direction is taken as an X-axis direction. One direction perpendicular to the Z-axis direction and perpendicular to the X-axis direction is taken as a Y-axis direction.

For example, the substrate 10 is light-transmissive. The substrate 10 is, for example, a light-transmissive substrate. A glass substrate may be used as the substrate 10. The substrate 10 may include, for example, a transparent resin substrate (e.g., a transparent plastic substrate, etc.).

For example, the first electrode 20 is light-transmissive. The first electrode 20 is, for example, an electrode that is light-transmissive. The first electrode 20 is formed on the first surface 10a of the substrate 10. For example, the first electrode 20 extends in the Y-axis direction and is arranged in the X-axis direction. In the case of such an arrangement, the first electrode 20 includes multiple openings and multiple electrode portions.

For example, the first electrode 20 includes a first portion 20p1, and a second portion 20p2 that is separated from the first portion 20p1 in a plane parallel to the first surface 10a. The first electrode 20 includes a third portion 20p3 that is provided between the first portion 20p1 and the second portion 20p2, a fourth portion 20p4 that is provided between the first portion 20p1 and the third portion 20p3, and a fifth portion 20p5 that is provided between the third portion 20p3 and the second portion 20p2. For example, the insulating layer 30 is formed on the first portion 20p1, the second portion 20p2, and the third portion 20p3. A portion of the second electrode layer 50 is formed on the fourth portion 20p4. The organic layer 40 is formed on the fifth portion 20p5.

As described below, an intermediate film may or may not be provided at a portion on the first electrode 20 when manufacturing the organic electroluminescent element according to the embodiment.

In the case where the intermediate film is used when manufacturing the organic electroluminescent element, for example, the first electrode 20 includes an oxide including at least one element selected from the group consisting of In, Sn, Zn, and Ti. The first electrode 20 may include, for example, indium oxide, zinc oxide, tin oxide, an indium tin oxide (ITO) film, fluorine-doped tin oxide (e.g., NESA, etc.), gold, platinum, silver, copper, etc.

In the case where the intermediate film is not used when manufacturing the organic electroluminescent element, for example, the first electrode 20 includes an oxide including at least one element selected from the group consisting of In, Sn, Zn, and Ti. The first electrode 20 may include, for example, indium oxide, zinc oxide, tin oxide, an indium tin oxide (ITO) film, fluorine-doped tin oxide (e.g., NESA or the like), etc. For example, the first electrode 20 may be formed on the substrate according to a method appropriately selected, by considering the suitability with the material included in the first electrode 20, from among a wet method such as a printing method, a coating method, or the like, a physical method such as vacuum vapor deposition, sputtering, ion plating, or the like, a chemical method such as CVD, plasma CVD, or the like, etc.

The first electrode 20 is, for example, a positive electrode. The positive electrode is not limited to these materials.

The insulating layer 30 is provided on the first electrode 20. The insulating layer 30 is provided in substantially a stripe configuration in the XY plane. Multiple trenches are formed between the insulating layers 30. In other words, the mutually-adjacent insulating layers 30 are provided with spacing interposed. For example, the insulating layers 30 are light-transmissive. For example, the insulating layers 30 are transparent.

The insulating layer 30 may include a material that is insulative. For example, a resin material such as a polyimide resin, an acrylic resin, etc., or an inorganic material such as a silicon oxide film (SiO₂), a silicon nitride film (SiN), a silicon oxynitride film, etc., may be used as the material of the insulating layer 30. The insulating layer 30 is not limited to these materials.

For example, the insulating layer 30 includes a first portion that contacts the first electrode 20, a second portion that contacts the second electrode layer 50, and a third portion that is provided between the first portion and the second portion to contact the organic layer 40 and the second electrode layer 50. The insulating layer 30 is disposed in parallel with the second electrode layer 50 in the Y-axis direction. In the embodiment, the organic electroluminescent element 110 has a bank structure of parallel banks.

The organic layer 40 is provided on the first electrode 20. The organic layer 40 includes an organic light-emitting layer. The organic layer 40 is formed between the insulating layers 30. The organic layer 40 is light-transmissive. For example, the organic layer 40 is light-transmissive in an unlit state.

The organic layer 40 includes a first portion that contacts the first electrode 20, a second portion that contacts the second electrode layer 50, and a third portion that contacts the insulating layer 30 and is provided between the first portion and the second portion. The thickness in the Z-axis direction of the organic layer 40 is thinner than the thickness in the Z-axis direction of the insulating layer 30. The length in the Z-axis direction of the third portion of the organic layer 40 is shorter than the length in the Z-axis direction of the third portion of the insulating layer 30.

The organic layer 40 includes, for example, multiple layers. The organic layer 40 includes, for example, a first layer, a second layer, and a third layer. In the case where the organic layer 40 includes a hole injection layer and/or a hole transport layer, these layers may be provided between the light-emitting layer and the first electrode 20. In the case where the organic layer 40 includes an electron injection layer and/or an electron transport layer, these layers may be provided between the light-emitting layer and the second electrode layer 50.

The second layer is an organic light-emitting layer. The second layer may include, for example, a material such as Alq3 (tris(8-hydroxyquinolinato)aluminum(III)), F8BT (poly(9,9-dioctylfluorene-co-benzothiadiazole), PPV (polyparaphenylene vinylene), etc. The second layer may include, for example, a mixed material of a host material and a dopant added to the host material. For example, CBP (4,4′,-bis(N-carbazolyl)-1,1′-biphenyl), BCP (2,9-dimethyl-4,7 diphenyl-1,10-phenanthroline), TPD (4,4′-bis-N-3 methyl phenyl-N-phenylamino biphenyl), PVK (polyvinyl carbazole), PPT (poly(3-phenylthiophene)), etc., may be used as the host material. For example, Flrpic (iridium(III)-bis(4,6-d i-fluorophenyl)-pyrid inate-N,C2′-picolinate), Ir(ppy)₃ (tris(2-phenylpyridine)iridium), Flr6 (bis(2,4-difluorophenylpyridinato)-tetrakis(1-pyrazolyl)borate-iridium(III)), etc., may be used as the dopant material. The light-emitting layer is not limited to these materials.

For example, the first layer functions as a hole injection layer. The hole injection layer includes, for example, at least one of PEDPOT:PPS (poly(3,4-ethylenedioxythiophene)-poly(styrenesulfonic acid)), CuPc (copper phthalocyanine), MoO₃ (molybdenum trioxide), or the like. For example, the first layer functions as a hole transport layer. The hole transport layer includes, for example, at least one of α-NPD (4,4′-bis[N-(1-naphthyl)-N-phenylamino]biphenyl), TAPC (1,1-bis[4-[N,N-di(p-tolyl)amino]phenyl]cyclohexane), m-MTDATA (4,4′,4″-tris[phenyl(m-tolyl)amino]triphenylamine), TPD (bis(3-methyl phenyl)-N,N′-diphenylbenzidine), TCTA (4,4′,4″-tri(N-carbazolyl)triphenylamine), or the like. For example, the first layer may have a stacked structure of a layer that functions as a hole injection layer and a layer that functions as a hole transport layer. For example, the first layer may include a layer of mixed materials of a hole injection material and a hole transport material. The first layer may include a layer other than the layer that functions as the hole injection layer and the layer that functions as the hole transport layer.

The third layer may include, for example, a layer that functions as an electron injection layer. The electron injection layer includes, for example, at least one of lithium fluoride, cesium fluoride, lithium quinoline complex, or the like. The third layer may include, for example, a layer that functions as an electron transport layer. The electron transport layer includes, for example, at least one of Alq3 (tris(8-hydroxyquinolinato)aluminum(III)), BAlq (bis(2-methyl-8-quinolinato)(p-phenylphenolate)aluminum), Bphen (bathophenanthroline), 3TPYMB (tris[3-(3-pyridyl)-mesityl]borane), or the like. For example, the third layer may have a stacked structure of a layer that functions as an electron injection layer and a layer that functions as an electron transport layer. The third layer may include a layer other than the layer that functions as the electron injection layer and the layer that functions as the electron transport layer.

The organic layer 40 contacts the first electrode 20. The organic layer 40 is electrically connected to the first electrode 20. The organic layer 40 contacts the light reflecting portion 50r of the second electrode layer 50. The organic layer 40 is electrically connected to the light reflecting portion 50r. In the specification, “electrical connection” includes the case where the objects to be connected are directly connected to each other and the case where another conductive member or the like is interposed between the objects.

A current is caused to flow in the organic layer 40 by using the first electrode 20 and the light reflecting portion 50r of the second electrode layer 50. The organic layer 40 emits light when the current flows in the organic layer 40. For example, the organic layer 40 emits light when the current flows in the organic layer 40. In the organic layer 40, holes and electrons are caused to recombine; and excitons are generated. For example, the organic layer 40 emits light by utilizing the emission of light when radiative deactivation of the excitons occurs. For example, an organic light-emitting layer inside the organic layer 40 emits light.

For example, the light that is emitted from the organic layer 40 is substantially white light. In other words, the light that is emitted from the organic electroluminescent element 110 is white light. Here, “white light” is substantially white and includes, for example, white light that is reddish, yellowish, greenish, bluish, violet-tinted, etc.

The hygroscopic material 70 absorbs water, etc., existing between the organic electroluminescent element 110 and the sealing substrate 80. A well-known material may be used as the hygroscopic material 70. It is sufficient for the material included in the hygroscopic material 70 to have the function of deterring the penetration into the element of substances such as moisture, oxygen, etc., that promote the element degradation. Specific examples include a metal such as In, Sn, Pb, Au, Cu, Ag, Al, Ti, Ni, etc., a metal oxide such as MgO, SiO, SiO₂, Al₂O₃, GeO, NiO, CaO, BaO, Fe₂O₃, Y₂O₃, TiO₂, etc., a metal nitride such as SiNₓ, SiNₓO_{y}, etc., a metal fluoride such as MgF₂, LiF, AlF₃, CaF₂, etc., polyethylene, polypropylene, polymethylmethacrylate, polyimide, polyurea, polytetrafluoroethylene, polychlorotrifluoroethylene, polydichlorodifluoroethylene, a copolymer of chlorotrifluoroethylene and dichlorodifluoroethylene, a copolymer obtained by copolymerizing a monomer mixture including tetrafluoroethylene and at least one type of comonomer, a fluorine-containing copolymer having ring structures in the copolymer backbone, a water-absorptive substance having a water absorption rate of 1% or more, a moisture-resistant substance having a water absorption rate of 0.1% or less, etc. The method for forming the hygroscopic material 70 is not particularly limited; and, for example, vacuum vapor deposition, sputtering, reactive sputtering, MBE (molecular beam epitaxy), a cluster ion beam method, ion plating, plasma polymerization (high frequency excitation ion plating), plasma CVD, laser CVD, thermal CVD, gas-source CVD, coating, printing, and transfer are applicable.

The sealing substrate 80 is, for example, light-transmissive. For example, the sealing substrate 80 transmits the light emitted from the organic layer 40. At least one of a glass substrate or a transparent resin may be used as the sealing substrate 80. In the embodiment, the sealing substrate 80 may be non-light-transmissive. A sealing body or the like is provided along the outer edge of the sealing substrate 80. The organic electroluminescent element 110 and the sealing substrate 80 are bonded using the sealing body.

As shown in FIG. 2A, the second electrode layer 50 is provided on the insulating layer 30, the organic layer 40, and an intermediate film 60. For example, the light reflecting portion 50r is light-reflective. The light reflectance of the second electrode layer 50 is higher than the light reflectance of the first electrode 20. In the specification, the state of having a reflectance that is higher than the light reflectance of the first electrode 20 is called light-reflective. For example, the second electrode layer 50 is provided by forming a conductive film having a light transmittance that is lower than the light transmittance of the first electrode 20.

A portion of the second electrode layer 50 is made transparent by a chemical reaction between the fourth portion 20p4 of the first electrode 20 and the material of the second electrode layer 50. The second electrode layer 50 that is formed on the fourth portion 20p4 is made transparent. The chemical reaction between the material of the second electrode layer 50 and the fourth portion 20p4 of the first electrode 20 progresses after the second electrode layer 50 is provided on the insulating layer 30 and the organic layer 40.

As shown in FIG. 2B, the intermediate film 60 may be formed on the fourth portion 20p4 of the first electrode 20 prior to forming the second electrode layer 50. A portion of the second electrode layer 50 is made transparent by the chemical reaction of the material of the second electrode layer 50 due to the intermediate film 60. The second electrode layer 50 that is formed on the intermediate film 60 is made transparent. The chemical reaction between the intermediate film 60 and the material of the second electrode layer 50 progresses after the second electrode layer 50 is provided on the insulating layer 30, the organic layer 40, and the intermediate film 60. The intermediate film 60 may remain between the first electrode 20 and the second electrode layer 50 after the portion of the second electrode layer 50 is made transparent. The intermediate film 60 may not remain between the first electrode 20 and the second electrode layer 50 after the portion of the second electrode layer 50 is made transparent.

The second electrode layer 50 includes a material that is made transparent by a material included in the first electrode 20 or the intermediate film 60. The second electrode layer 50 includes, for example, aluminum. For example, an aluminum film may be used as the second electrode layer 50. In the case where the second electrode layer 50 is an aluminum film, the first electrode 20 is, for example, an ITO film. The second electrode layer 50 is, for example, a negative electrode.

A portion of the second electrode layer 50 may be made transparent by the chemical reaction between the material of the first electrode 20 and the material of the second electrode layer 50. A portion of the second electrode layer 50 may be made transparent by the chemical reaction between the material of the intermediate film 60 and the material of the second electrode layer 50. Thereby, in the organic electroluminescent element 110 according to the embodiment, the second electrode layer 50 includes the light reflecting portion 50r that is light-reflective, and the light-transmitting portion 50t. The light reflecting portion 50r includes a conductive portion 50c that contacts the organic layer 40. The conductive portion 50c corresponds to a light emitter.

The second electrode layer 50 includes, for example, at least one of silver, magnesium, or calcium. An alloy of silver and magnesium may be used as the second electrode layer 50. The alloy of silver and magnesium may include calcium.

The second electrode layer 50 may have a single-layer structure. The second electrode layer 50 may have a stacked structure. In the case where the second electrode layer 50 has a stacked structure, the layer on the side opposing the first electrode 20 may be a layer including an alkaline metal or an alkaline earth metal. For example, lithium, sodium, potassium, rubidium, cesium, etc., may be used as the alkaline metal. Beryllium, magnesium, calcium, strontium, barium, radium, etc., may be used as the alkaline earth metal. The method for forming the second electrode layer 50 is not particularly limited and may be performed according to a known method. For example, the formation may be performed according to a method appropriately selected by considering suitability to the material included in the second electrode layer 50 described above from among a wet method such as a printing method, a coating method, or the like, a physical method such as vacuum vapor deposition, sputtering, ion plating, or the like, a chemical method such as CVD, plasma CVD, etc. For example, vacuum vapor deposition or sputtering may be used in the case where a metal or the like is selected as the material of the negative electrode.

For example, these materials of the second electrode layer 50 are made transparent by a chemical reaction with indium tin oxide which is the material of the first electrode. In the case where indium tin oxide is used as the first electrode 20, the light-transmitting portion 50t can be formed by causing the chemical reaction between the second electrode layer 50 and the fourth portion 20p4 of the first electrode 20 without providing the intermediate film 60.

These materials of the second electrode layer 50 are made transparent by a chemical reaction with the material of the intermediate film 60 described below. In the case where the material described below is used as the intermediate film 60, the light-transmitting portion 50t can be formed on the fourth portion 20p4 of the first electrode 20 by causing a chemical reaction between the intermediate film 60 and the material of the second electrode layer 50.

The intermediate film 60 is provided on the first electrode 20 between a pair of insulating layers 30. The intermediate film 60 is provided in substantially a stripe configuration in the XY plane. The intermediate film 60 includes a film having multiple rectangular configurations in the XY plane. For example, the intermediate film 60 may be provided in a lattice configuration in the XY plane.

The intermediate film 60 includes a substance that promotes the reaction with the material of the second electrode layer 50. The intermediate film 60 is, for example, an oxidizing agent. In the case where an aluminum film is used as the second electrode layer 50, for example, an yttrium-based copper oxide high temperature superconductor of YBa₂Cu₃O₇ may be used as the oxidizing agent. A copper oxide high temperature superconductor in which Y is replaced with lanthanum, neodymium, samarium, europium, gadolinium, dysprosium, holmium, erbium, thulium, ytterbium, lutetium, etc., may be used. For example, a material that has an oxygen-deficient perovskite structure may be used as the oxidizing agent. Potassium permanganate, potassium dichromate, a rare-earth copper oxide agent, etc., may be used as the oxidizing agent. Sputtering may be used in the case where the intermediate film 60 is formed using a rare-earth copper oxide agent. An indium tin oxide (ITO) film may be used as the intermediate film 60.

In the case where the first electrode 20 includes ITO, the second electrode layer 50 includes aluminum; and the intermediate film 60 includes an oxidizing agent (YBa₂Cu₃O₇). For example, a chemical reaction such as that of Formula (1) recited below occurs.

3YBa₂Cu₃O₇+2Al→3YBa₂Cu₃O₆+Al₂O₃ (1)

By the reaction equation of Formula (1), a portion of the second electrode layer 50 includes aluminum oxide; and the light-transmitting portion 50t is formed. In other words, the second electrode layer 50 that is provided on the fourth portion 20p4 of the first electrode 20 becomes the light-transmitting portion 50t. An oxidation reaction with aluminum occurs due to the oxidizing agent. A portion (the light-transmitting portion 50t) of the second electrode layer 50 is provided with transmissivity. YBa₂Cu₃O₇ is transmissive when YBa₂Cu₃O₇ contacts aluminum.

In the organic electroluminescent element of FIGS. 2A and 2B, the intermediate film 60 is provided between the first electrode 20 and the second electrode layer 50. For the reaction between the first electrode 20 and the second electrode layer 50, the first electrode 20 and the second electrode layer 50 may not contact each other. A layer may be formed between the first electrode 20 and the intermediate film 60.

A layer may be formed in an island configuration between the second electrode layer 50 and the intermediate film 60. In other words, the second electrode layer 50 includes a portion that contacts the intermediate film 60, and a portion that opposes the intermediate film 60 with the layer having the island configuration interposed. A chemical reaction occurs between the second electrode layer 50 and the intermediate film 60 at the portion of the second electrode layer 50 contacting the intermediate film 60. The layer that has the island configuration is, for example, the third layer.

The chemical reaction of the aluminum due to the oxidizing agent substantially does not occur at the light reflecting portion 50r. The light reflecting portion 50r is not provided with transmissivity. The light reflecting portion 50r is light-reflective. The light reflecting portion 50r substantially does not transmit the light emitted from the organic layer 40.

For example, the second electrode layer 50 is formed by forming a conductive film on the insulating layer 30, the organic layer 40, and the intermediate film 60. The conductive film has a light transmittance that is lower than the light transmittance of the first electrode 20. In such a case, the light transmittance of the portion of the conductive film positioned on the intermediate film is higher than the light transmittance of the portion of the conductive film positioned on the organic light-emitting layer.

By using the intermediate film 60 to provide transmissivity to a portion of the second electrode layer 50 in the organic electroluminescent element 110, the light-transmitting portion 50t that is light-transmissive and the light reflecting portion 50r that is light-reflective are provided in the second electrode layer 50. For example, the organic electroluminescent element 110 according to the embodiment corresponds to a transmission-type organic electroluminescent element.

In such a transmission-type organic electroluminescent element, in the case where a viewer views the non-light-emitting surface from the light-emitting surface side, it is difficult for the viewer to view through the panel when a current is provided due to the high light emission luminance. When the current is not provided, the viewer can see the non-light-emitting surface from the light-emitting surface side and can see the light-emitting surface from the non-light-emitting surface side.

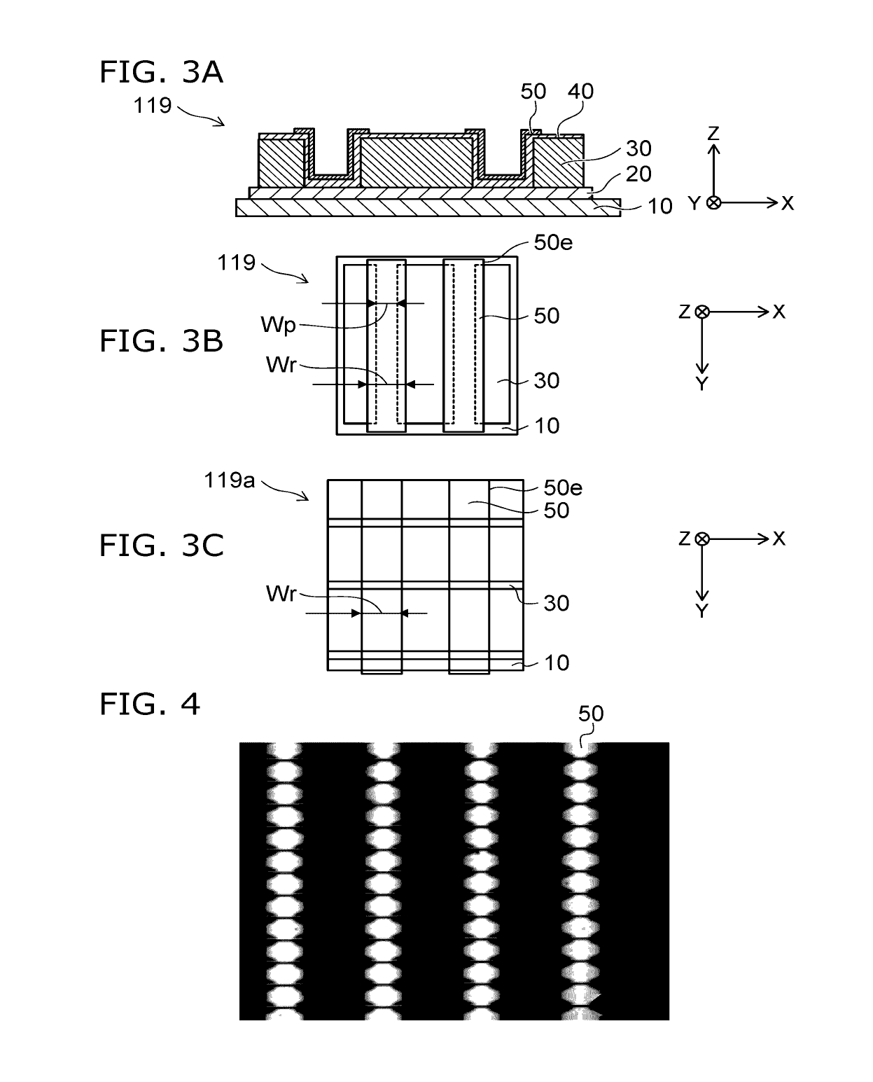

FIG. 3A to FIG. 3C are schematic views showing organic electroluminescent elements of a reference example.

FIG. 4 is a microscope photograph showing a portion of the organic electroluminescent element of the reference example.

FIG. 3A shows the cross section of the transmission-type organic electroluminescent element. FIG. 3B and FIG. 3C show top views of the transmission-type organic electroluminescent element as viewed from the Z-axis direction. FIG. 4 is a light emission photograph of the second electrode layer 50 of the transmission-type organic electroluminescent element of FIG. 3C.

As shown in FIG. 3A, the substrate 10, the first electrode 20, the insulating layer 30, the organic layer 40, and the second electrode layer 50 are provided in an organic electroluminescent element 119.

In such a transmission-type organic electroluminescent element 119, the second electrode layer 50 is provided in substantially a stripe configuration in the XY plane on the organic layer 40. Setting the width of the second electrode layer 50 to be narrow makes it difficult to see the second electrode layer 50. The transmission-type organic electroluminescent element 119 is provided with transmissivity by providing openings in the second electrode layer 50.

An end portion 50e of the second electrode layer 50 is exposed because the second electrode layer 50 is formed in a fine stripe configuration.

FIG. 3B shows the organic electroluminescent element 119 that has a structure (a parallel bank structure) in which the extension direction of the second electrode layer 50 having the stripe configuration is parallel to the extension direction of the insulating layer 30. The end portion 50e of the second electrode layer 50 is exposed. The greater part of the second electrode layer 50 covers the insulating layer 30. The storage life of the second electrode layer 50 undesirably is short because at least one of water or oxygen penetrates easily from the end portion 50e of the second electrode layer 50.

FIG. 3C shows an organic electroluminescent element 119a that has a structure (a perpendicular bank structure) in which the extension direction of the second electrode layer 50 having the stripe configuration is perpendicular to the extension direction of the insulating layer 30. The insulating layer 30 is disposed perpendicularly to the second electrode layer 50. The width of the second electrode layer 50 contributing to the light emission (the width of the light-emitting region) can be wider for the organic electroluminescent element 119a that has the perpendicular bank structure compared to the organic electroluminescent element 119 having the parallel bank structure. The light emission surface area increases. For example, a width Wp of the second electrode layer 50 contributing to the light emission in the parallel bank structure is about 100 micrometers. A width Wr of the second electrode layer 50 contributing to the light emission in the perpendicular bank structure is about 150 micrometers.

The proportion of the end portion 50e of the second electrode layer 50 that is exposed is high for the organic electroluminescent element 119a having the bank structure of the perpendicular banks compared to the organic electroluminescent element 119 having the bank structure of the parallel banks. The second electrode layer 50 and the insulating layer 30 are disposed perpendicularly. The second electrode layer 50 intersects the upper portion of the insulating layer 30. At least one of water or oxygen penetrates easily into the interior of the organic electroluminescent element 119a from the end portion 50e of the second electrode layer 50. Therefore, the storage life of the second electrode layer 50 is even shorter for the organic electroluminescent element 119a compared to the organic electroluminescent element 119 having the bank structure of the parallel banks.

As shown in FIG. 4, the second electrode layer 50 is eroded by at least one of water or oxygen penetrating from the exposed end portion 50e. The material that is included in the end portion 50e of the second electrode layer 50 degrades. The end portion 50e of the second electrode layer 50 peels. In particular, the locations where the second electrode layer 50 and the insulating layer 30 intersect become non-light-emitting regions. The end portion 50e of the second electrode layer 50 does not contribute to the light emission. The non-light-emitting regions advance from the end portion 50e of the second electrode layer 50.

In the organic electroluminescent element 110 according to the embodiment, the second electrode layer 50 is formed on the entire surface of the light-emitting region; and a portion of the second electrode layer 50 is provided with transmissivity by utilizing the oxidation reaction of the second electrode layer 50 due to the intermediate film 60. Thereby, the second electrode layer 50 in which the end portion is not exposed easily is formed. The end portion of the organic layer 40 also is not exposed easily. The portion (the light-transmitting portion 50t) that is oxidized suppresses (e.g., shields) the penetration of the at least one of water or oxygen because the portion that is oxidized is a metal oxide film. In the organic electroluminescent element 110, the storage life of the second electrode layer 50 can be improved because the moisture and/or the oxygen does not penetrate easily from the end portion 50e of the second electrode layer 50.

In a transmission-type organic electroluminescent element, the visibility of the second electrode layer 50 itself is suppressed and the background image can be viewed better by setting the width of the second electrode layer 50 (the conductive portion) to be finer and setting the pitch spacing of the second electrode layer 50 to be narrower. In such a case, higher precision is necessary in the formation of the second electrode layer 50. For example, in the case where the width of the second electrode layer 50 is set to be finer and the pitch spacing of the second electrode layer 50 is made narrow, the configuration of the mask for forming the second electrode layer 50 has a fine wire configuration; and because the pattern is fine, the fine wire-shaped portions of the mask distort. The strength of the mask decreases. In such a case, the risk of contact between the mask and the organic layer 40 is high. For example, in the case where the distance between the mask and the object is large, the material that is to be vacuum vapor-deposited undesirably diffuses after passing through the mask; and the formation precision decreases. The mask and the object are caused to be proximal to each other to increase the formation precision in the vacuum vapor deposition. Therefore, the risk of contact between the mask and the organic layer 40 is higher when the formation precision of the second electrode layer 50 is increased.

For example, vacuum vapor deposition may be used to form the second electrode layer 50 in substantially a stripe configuration in the XY plane. The mask (e.g., a metal mask) for patterning the second electrode layer 50 easily contacts the organic layer 40. The organic layer 40 is damaged if the mask contacts the organic layer 40. When the light-emitting region is damaged, for example, the first electrode 20 and the second electrode layer 50 contact each other. Shorts are caused when the first electrode 20 and the second electrode layer 50 contact each other. For example, defects having line configurations are caused when the second electrode layer 50 is formed in a fine stripe configuration.

In the organic electroluminescent element 110 according to the embodiment, the formation pattern of the second electrode layer 50 can be controlled on the substrate 10 side when forming the second electrode layer 50. The precision necessary for the metal mask is relaxed. The likelihood of defects of the second electrode layer 50 occurring due to the fine metal mask can be reduced. The likelihood of the shorts occurring due to the contact between the organic layer 40 and the metal mask can be reduced. The yield of the organic electroluminescent element increases.

According to the embodiment of the invention, a highly reliable organic electroluminescent element is provided.

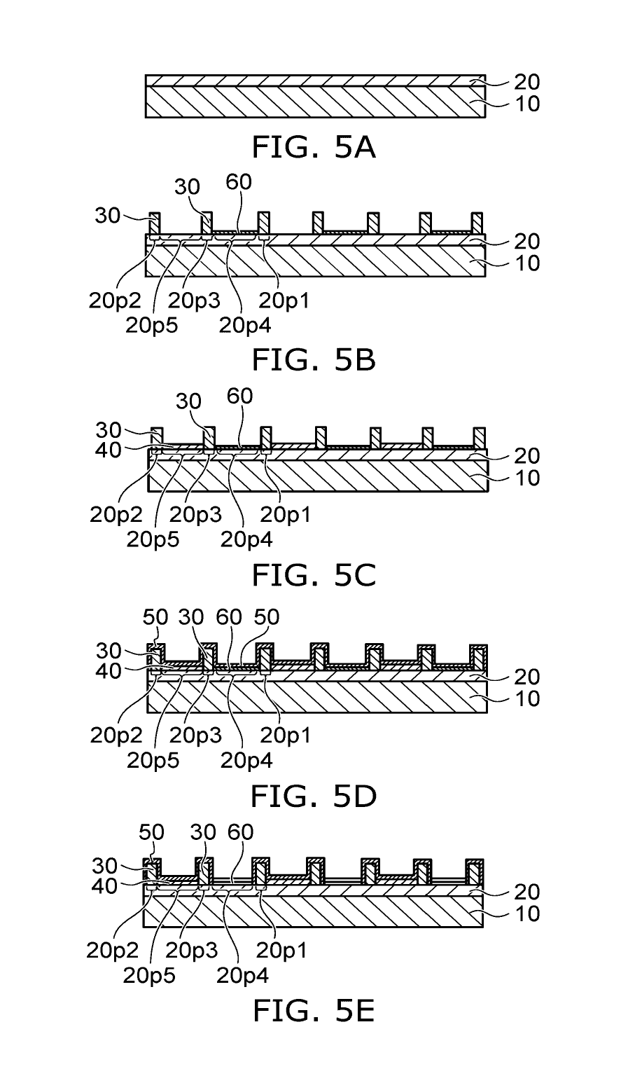

FIG. 5A to FIG. 5E show manufacturing processes of the organic electroluminescent element according to the first embodiment. Here, the manufacturing processes of the organic electroluminescent element according to the first embodiment are described for the case where the intermediate film 60 is provided.

In FIG. 5A, the first electrode 20 is formed on the substrate 10. For example, the first electrode 20 is formed by photolithography.

For example, the first electrode 20 includes the first portion 20p1, and the second portion 20p2 that is separated from the first portion 20p1 in a plane parallel to the first surface 10a. The first electrode 20 includes the third portion 20p3 that is provided between the first portion 20p1 and the second portion 20p2, the fourth portion 20p4 that is provided between the first portion 20p1 and the third portion 20p3, and the fifth portion 20p5 that is provided between the third portion 20p3 and the second portion 20p2.

In FIG. 5B, the insulating layer 30 and the intermediate film 60 are patterned on the first electrode 20. For example, the insulating layer 30 is formed by photolithography.

The intermediate film 60 is provided on the first electrode 20 between the insulating layer 30. The insulating layer 30 and the intermediate film 60 are provided in substantially stripe configurations in the XY plane. For example, the insulating layer 30 is formed on the first portion 20p1, the second portion 20p2, and the third portion 20p3 of the first electrode 20. The intermediate film 60 is formed on the fourth portion 20p4 of the first electrode 20.

In FIG. 5C, the organic layer 40 is formed. The organic layer 40 is provided on the first electrode 20. The organic layer 40 is formed in a portion of the multiple trenches formed between the insulating layer 30. For example, the organic layer 40 is formed on the fifth portion 20p5 of the first electrode 20.

In FIG. 5D, the second electrode layer 50 is formed on the insulating layer 30, the organic layer 40, and the intermediate film 60. The second electrode layer 50 is formed on the entire surface of the light-emitting region. For example, the second electrode layer 50 is provided by forming a conductive film having a light transmittance that is lower than the light transmittance of the first electrode 20.

The second electrode layer 50 is formed by vacuum vapor deposition. The second electrode layer 50 is formed by sputtering.

In FIG. 5E, the portion where the second electrode layer 50 and the intermediate film 60 contact each other is made transparent. The light-transmitting portion 50t is formed in the second electrode layer 50. For example, the light transmittance of the portion of the conductive film positioned on the intermediate film 60 is higher than the light transmittance of the portion of the conductive film positioned on the organic layer 40.

An oxidation reaction with the aluminum occurs due to an oxidizing agent (YBa₂Cu₃O₇) in the case where the first electrode 20 includes ITO, the second electrode layer 50 includes aluminum, and the intermediate film 60 includes the oxidizing agent. A portion of the second electrode layer 50 includes aluminum oxide; and the second electrode layer 50 is provided with transmissivity.

When the portion of the second electrode layer 50 is made transparent, the organic electroluminescent element 110 may be heated to provide the portion of the second electrode layer 50 with uniform transmissivity in the oxidation reaction with the aluminum. The temperature at which the organic electroluminescent element 110 is heated is, for example, not less than 30° C. and not more than 150° C.

When making the portion of the second electrode layer 50 transparent, a current may be applied to the organic electroluminescent element 110 to promote the oxidation reaction with the aluminum. The current that is applied to the organic electroluminescent element 110 is, for example, not less than 0.1 mA and not more than 1000 mA.

In the case where the light-transmitting portion 50t of the second electrode layer 50 is formed without the intermediate film 60, the process of forming the intermediate film 60 can be omitted. To cause the chemical reaction between the material of the first electrode 20 and the material of the second electrode layer 50, the organic electroluminescent element may be heated after forming the second electrode layer 50. A current may be applied to the organic electroluminescent element to cause the chemical reaction between the material of the first electrode 20 and the material of the second electrode layer 50. To cause the chemical reaction between the material of the first electrode 20 and the material of the second electrode layer 50, the chemical reaction may be performed in a trace oxygen atmosphere, an atmosphere in which the moisture concentration is increased, or an atmosphere of both.

### Second Embodiment

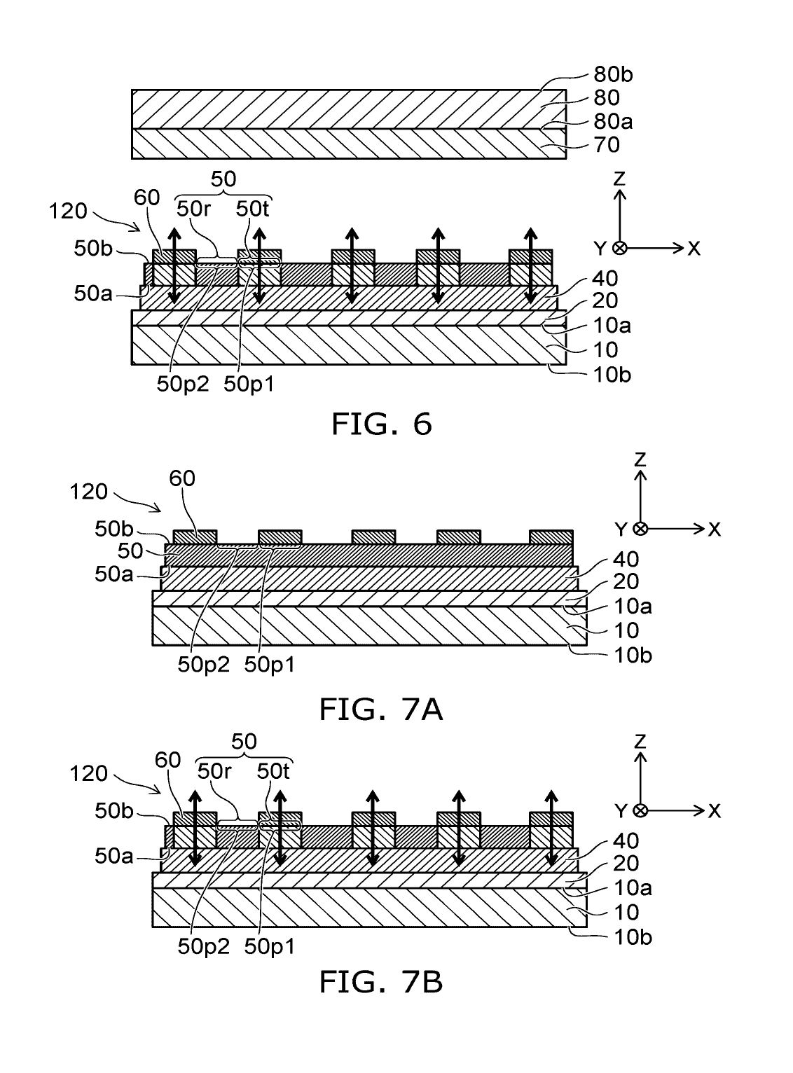

FIG. 6 is a schematic cross-sectional view showing an organic electroluminescent element according to a second embodiment.

The manufacturing of the organic electroluminescent element according to the second embodiment includes a process of forming the intermediate film 60.

FIG. 6 shows the organic electroluminescent element 120. FIG. 7A shows the organic electroluminescent element 120 when forming the intermediate film 60 in substantially a stripe configuration on the second electrode layer 50. FIG. 7B shows the organic electroluminescent element 120 after forming the intermediate film 60 when the chemical reaction between the material of the first electrode 20 and the material of the second electrode layer 50 has progressed due to the intermediate film 60.

As shown in FIG. 6, the substrate 10, the first electrode 20, the organic layer 40, the second electrode layer 50, and the intermediate film 60 are provided in the organic electroluminescent element 120. The organic electroluminescent element 120 is sealed with the sealing substrate 80 with the hygroscopic material 70 interposed.

The substrate 10 has the first surface 10a and the second surface 10b. The second surface 10b is the surface on the side opposite to the first surface 10a. The sealing substrate 80 has the third surface 80a and the fourth surface 80b. The fourth surface 80b is the surface on the side opposite to the third surface 80a. The second electrode layer 50 has a fifth surface 50a and a sixth surface 50b. The sixth surface 50b is the surface on the side opposite to the fifth surface 50a. The first surface 10a of the substrate 10 opposes the third surface 80a of the sealing substrate 80.

The first electrode 20 is formed on the first surface 10a of the substrate 10. The organic layer 40 is provided on the first electrode 20. At least one of an insulating layer or a supplemental interconnect layer may be provided between the first electrode 20 and the second electrode layer 50.

The supplemental interconnect layer includes, for example, at least one element selected from the group consisting of Mo, Ta, Nb, Al, Ni, and Ti. The supplemental interconnect layer is, for example, a mixed film including an element selected from the group. The supplemental interconnect layer may be, for example, a stacked film including these elements. The supplemental interconnect layer may include, for example, a stacked film of Nb/Mo/Al/Mo/Nb. For example, the supplemental interconnect layer functions as an auxiliary electrode that suppresses the potential drop of the first electrode 20. For example, the supplemental interconnect layer may function as a layer that protects from the direct contact between the first electrode 20 and the second electrode layer 50. The supplemental interconnect layer may function as a lead electrode for current supply.

As shown in FIG. 7A, the second electrode layer 50 is formed on the organic layer 40. The second electrode layer 50 is formed on the entire surface of the light-emitting region. The fifth surface 50a of the second electrode layer 50 contacts the organic layer 40. A portion of the sixth surface 50b of the second electrode layer 50 contacts the intermediate film 60.

As shown in FIG. 7B, a portion of the second electrode layer 50 is made transparent by a chemical reaction between the material of the second electrode layer 50 and the material of the first electrode 20 due to the intermediate film 60. After the second electrode layer 50 is provided on the organic layer 40, the chemical reaction between the material of the first electrode 20 and the material of the second electrode layer 50 progresses due to the intermediate film 60.

For example, the second electrode layer 50 is formed of a conductive film including a first portion 50p1 and a second portion 50p2 that are separated from each other in a direction (the X-direction) intersecting the direction from the first electrode 20 toward the organic layer 40. The intermediate film 60 is formed at the first portion 50p1. In such a case, the light transmittance of the first portion 50p1 of the second electrode layer 50 is higher than the light transmittance of the second portion 50p2 of the second electrode layer 50.

The portion of the second electrode layer 50 is made transparent by the chemical reaction between the material of the first electrode 20 and the material of the second electrode layer 50. Thereby, in the organic electroluminescent element 110 according to the embodiment, the second electrode layer includes the light-transmitting portion 50t and the light-reflective light reflecting portion 50r. The light reflecting portion 50r corresponds to the conductive portion 50c that contacts the organic layer 40.

The intermediate film 60 is provided in substantially a stripe configuration in the XY plane on the second electrode layer 50. The intermediate film 60 includes a film having multiple rectangular configurations in the XY plane. For example, the intermediate film 60 may be provided in a lattice configuration in the XY plane.

The intermediate film 60 acts as a substance that promotes the reaction between the material of the first electrode 20 and the material of the second electrode layer 50. The intermediate film 60 is, for example, an oxidizing agent. An indium tin oxide (ITO) film may be used as the intermediate film 60.

The light-transmitting portion 50t is formed by a portion of the second electrode layer 50 including aluminum oxide in the case where the first electrode 20 includes ITO, the second electrode layer 50 includes aluminum, and the intermediate film 60 includes an oxidizing agent (YBa₂Cu₃O₇). The oxidation reaction with the aluminum occurs due to the oxidizing agent. The portion (the light-transmitting portion 50t) of the second electrode layer 50 is provided with transmissivity.

The chemical reaction with the aluminum due to the oxidizing agent does not occur in the light reflecting portion 50r. Transmissivity is not provided to the light reflecting portion 50r. Because the light reflecting portion 50r is light-reflective, the light reflecting portion 50r does not transmit the light emitted from the organic layer 40.

A portion of the second electrode layer 50 includes aluminum oxide due to the contact between the second electrode layer 50 and the intermediate film 60 in the case where the first electrode 20 includes ITO, the second electrode layer 50 includes aluminum, and the intermediate film 60 includes ITO. The light-transmitting portion 50t is formed by the oxidation reaction between the ITO and the aluminum. The portion (the light-transmitting portion 50t) of the second electrode layer 50 is provided with transmissivity.

By providing the portion of the second electrode layer 50 with transmissivity due to the intermediate film 60, the organic electroluminescent element 120 includes the second electrode layer 50 that includes the light-transmissive light-transmitting portion 50t and the light-reflective light reflecting portion 50r. For example, the organic electroluminescent element 120 of the embodiment corresponds to a transmission-type organic electroluminescent element.

In the organic electroluminescent element 120 according to the embodiment, the second electrode layer 50 is formed on the entire surface of the light-emitting region; and a portion of the second electrode layer 50 is provided with transmissivity by utilizing the oxidation reaction between the first electrode 20 and the second electrode layer 50 due to the intermediate film 60. Thereby, the second electrode layer 50 in which the end portion is not exposed easily is formed. The end portion of the organic layer 40 also is not exposed easily. The portion (the light-transmitting portion 50t) that is oxidized suppresses the penetration of at least one of water or oxygen because the portion that is oxidized is a metal oxide film. In the organic electroluminescent element 120, the storage life of the second electrode layer 50 can be improved because the at least one of water or oxygen does not penetrate easily from the end portion 50e of the second electrode layer 50.

According to the embodiment of the invention, a highly reliable organic electroluminescent element is provided.

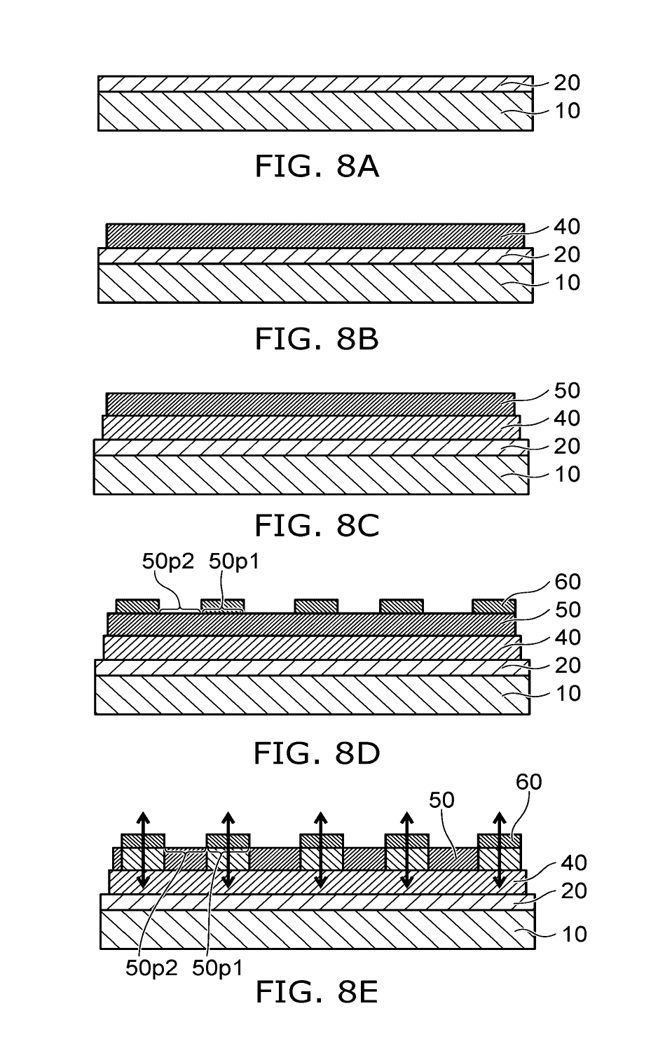

FIG. 8A to FIG. 8E show manufacturing processes of the organic electroluminescent element according to the second embodiment.

In FIG. 8A, the first electrode 20 is formed on the substrate 10. For example, the first electrode 20 is formed by photolithography.

The organic layer 40 is formed in FIG. 8B. The organic layer 40 is provided on the first electrode 20.

In FIG. 8C, the second electrode layer 50 is formed on the organic layer 40. The second electrode layer 50 is formed on the entire surface of the light-emitting region.

In FIG. 8D, the intermediate film 60 is provided on the second electrode layer 50. The intermediate film 60 is provided in substantially a stripe configuration in the XY plane.

In FIG. 8E, the portion where the second electrode layer 50 and the intermediate film 60 contact each other is made transparent. The light-transmitting portion 50t is formed in the second electrode layer 50.

For example, the second electrode layer 50 is formed of a conductive film including the first portion 50p1 and the second portion 50p2 that are separated from each other in a direction (the X-direction) intersecting the direction from the first electrode 20 toward the organic layer 40. The intermediate film 60 is formed at the first portion 50p1. In such a case, the light transmittance of the first portion 50p1 of the second electrode layer 50 is higher than the light transmittance of the second portion 50p2 of the second electrode layer 50.

An oxidation reaction with the aluminum occurs due to an oxidizing agent (YBa₂Cu₃O₇) in the case where the first electrode 20 includes ITO, the second electrode layer 50 includes aluminum, and the intermediate film 60 includes the oxidizing agent. The second electrode layer 50 is provided with transmissivity by a portion of the second electrode layer 50 including aluminum oxide.

According to the embodiments, a highly reliable organic electroluminescent element and a method for manufacturing the organic electroluminescent element are provided.

The organic electroluminescent element 110 of the embodiment may be used in a lighting device. In the case where the organic electroluminescent element is a transmission-type organic electroluminescent element, such a lighting device has the function of transmitting a background image in addition to the lighting function.

Hereinabove, embodiments of the invention are described with reference to specific examples. However, the invention is not limited to these specific examples. For example, one skilled in the art may similarly practice the invention by appropriately selecting specific configurations of components included in the organic electroluminescent element such as the substrate, the first electrode, the insulating layer, the organic layer, the intermediate film, the second electrode layer, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all organic electroluminescent elements practicable by an appropriate design modification by one skilled in the art based on the organic electroluminescent elements described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing an organic electroluminescent element, comprising:
forming a first electrode on a first surface of a substrate, the first electrode being light-transmissive, the first electrode including a first portion, a second portion, a third portion, a fourth portion, and a fifth portion, the second portion being separated from the first portion in a plane parallel to the first surface, the third portion being provided between the first portion and the second portion, the fourth portion being provided between the first portion and the third portion, the fifth portion being provided between the third portion and the second portion;
forming an insulating layer on the first portion, the second portion, and the third portion;
forming an organic layer on the fifth portion; and
forming a conductive layer having a light transmittance lower than a light transmittance of the first electrode so that the conductive layer is formed on the fourth portion, the insulating layer, and the organic layer, and causing a light transmittance of a portion of the conductive layer positioned on the fourth portion to be higher than a light transmittance of a portion of the conductive layer positioned on the organic layer.

2. The method according to claim 1, comprising forming an intermediate film on the fourth portion after the forming of the insulating layer and prior to the forming of the conductive layer.

3. The method according to claim 2, wherein the intermediate film includes a compound including oxygen.

4. The method according to claim 2, wherein the intermediate film includes an oxidizing agent.

5. The method according to claim 4, wherein the oxidizing agent includes copper oxide.

6. The method according to claim 4, wherein the oxidizing agent includes YBa₂Cu₃O₇.

7. The method according to claim 2, wherein the intermediate film includes indium tin oxide.

8. The method according to claim 1, wherein the conductive layer includes aluminum.

9. The method according to claim 1, wherein the first electrode includes indium tin oxide.

10. A method for manufacturing an organic electroluminescent element, comprising:
forming an organic layer on a first electrode, the first electrode being light-transmissive;
forming a conductive film on the organic layer, the conductive film having a light transmittance lower than a light transmittance of the first electrode, the conductive film including a first portion and a second portion separated from each other in a direction intersecting a direction from the first electrode toward the organic layer; and
forming an intermediate film on the first portion, and causing a light transmittance of the first portion to be higher than a light transmittance of the second portion.

11. The method according to claim 10, wherein the intermediate film includes a compound including oxygen.

12. The method according to claim 10, wherein the intermediate film includes an oxidizing agent.

13. The method according to claim 12, wherein the oxidizing agent includes copper oxide.

14. The method according to claim 12, wherein the oxidizing agent includes YBa₂Cu₃O₇.

15. The method according to claim 10, wherein the intermediate film includes indium tin oxide.

16. The method according to claim 10, wherein the conductive film includes aluminum.

17. The method according to claim 10, wherein the first electrode includes indium tin oxide.

18. An organic electroluminescent element, comprising:
a substrate having a first surface,
a first electrode provided on the first surface, the first electrode being light-transmissive, the first electrode including a first portion, a second portion, a third portion, a fourth portion, and a fifth portion, the second portion being separated from the first portion in a plane parallel to the first surface, the third portion being provided between the first portion and the second portion, the fourth portion being provided between the first portion and the third portion, the fifth portion being provided between the third portion and the second portion;
an insulating layer provided on the first portion, the second portion, and the third portion;
an intermediate film provided on the fourth portion;
an organic layer provided on the fifth portion; and
a conductive film provided on the insulating layer, the intermediate film, and the organic layer,
a light transmittance of a portion of the conductive film positioned on the intermediate film being higher than a light transmittance of a portion of the conductive film positioned on the organic layer.

19. The organic electroluminescent element according to claim 18, wherein the intermediate film includes a compound including oxygen.

20. The organic electroluminescent element according to claim 18, wherein the intermediate film includes an oxidizing agent.
